(19) United States
(12) Patent Application Publication
(10) Pub. No.: US 2021/0194482 A1
(43) Pub. Date: Jun. 24, 2021

(54) ELECTRICAL APPARATUS WITH TOUCH OPERATION SENSING DEVICE AND SENSING COIL

(71) Applicant: SAMSUNG ELECTRO-MECHANICS CO., LTD., Suwon-si (KR)

(72) Inventors: Woo Young Choi, Suwon-si (KR); Jung Eui Park, Suwon-si (KR); Joo Hyoung Lee, Suwon-si (KR); Joo Yul Ko, Suwon-si (KR); Yong Woon Ji, Suwon-si (KR)

(73) Assignee: SAMSUNG ELECTRO-MECHANICS CO., LTD., Suwon-si (KR)

(21) Appl. No.: 16/843,947

(22) Filed: Apr. 9, 2020

(30) Foreign Application Priority Data
Dec. 23, 2019 (KR) 10-2019-0172974

(51) Int. Cl. H03K 17/96; H01F 27/28; H01F 27/32; G06F 3/044

(52) U.S. Cl. CPC H03K 17/962; G06F 3/0443; H01F 27/32; H01F 27/2804

(57) ABSTRACT

A touch operation sensing device includes a touch interaction switch integrally formed with a housing and including a conductive first touch member having a first insulated hole, and a sensing coil disposed inside the first touch member. The touch operation sensing device includes an oscillation circuit and a touch detection circuit. The oscillation circuit is configured to generate an oscillation signal having a variable resonance frequency based on a touch capacitance generated by an interaction with a touch body touching the first touch member, the first insulated hole, and the sensing coil. The touch detection circuit is configured to detect a touch interaction using the oscillation signal from the oscillation circuit.

### CROSS-REFERENCE TO RELATED APPLICATIONS

This application claims the benefit under 35 USC 119(a) of Korean Patent Application No. 10-2019-0172974 filed on Dec. 23, 2019 in the Korean Intellectual Property Office, the entire disclosure of which is incorporated herein by reference for all purposes.

### BACKGROUND

### 1. Field

The following description relates to an electrical apparatus with a touch operation sensing device and sensing coil.

### 2. Description of Related Art

It is typically preferable that wearable devices have a thinner, simpler, and cleaner form factor. To that extent, typical mechanical switches are rarely being implemented in wearable devices. Dustproof and waterproof technologies are currently being implemented, therefore resulting in models that have a smooth and unified form factor.

Currently, technologies such as touch-on-metal (ToM) technology that sense touches on metal, capacitance sensing technologies that use touch panels, a micro-electro-mechanical-system (MEMS) technology, a force-touching function, and micro strain gauges are being developed.

In typical mechanical switches, a relatively large amount of internal or inner space may be needed to implement switch functions. Additionally, in structures in which a switch is not integrated with an external case, the mechanical switches may result in a structure that has an externally protruding design. Accordingly, a structure that has a mechanical switch may result in an obtrusive design, and may need a large inner space.

Additionally, there may be a risk of electric shock if direct contact is made with the electrically connected mechanical switch, and i dust-proofing and waterproofing implementations may be difficult due to structural deficiencies of the mechanical switch.

In the typical switching device, it may be beneficial to improve the structures of the metal case and the inductor element to improve the sensing sensitivity of the touch interaction in relation to the internal inductor element.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect, a touch operation sensing device comprising a touch interaction switch integrally formed with a housing, the touch interaction switch comprising a first conductive touch member including a first insulated hole, the touch operation sensing device comprising a sensing coil disposed inside the first touch member, an oscillation circuit connected to the sensing coil, and configured to generate an oscillation signal having a variable resonance frequency based on a touch capacitance generated when the first touch member is touched, and a touch detection circuit configured to detect a touch operation based on the generated oscillation signal, wherein the sensing coil includes a first inductance wiring comprising a first terminal and a second terminal, and configured to face the first insulated hole; and a first conductive plate electrically connected to one of the first terminal and the second terminal, and configured to form a capacitance with a touch object through the first insulated hole.

The sensing coil may be disposed to be spaced apart from an inner side of the first touch member.

The device may further include a first insulating member disposed between an inner side of the first touch member and the sensing coil.

The first insulated hole may include a through-portion that penetrates through the first touch member and an insulating material that fills the through-portion.

The first conductive plate may be disposed to face the first insulated hole.

The oscillation circuit may include a capacitance circuit connected in parallel with the first inductance wiring through a first terminal and a second terminal; and an amplifying circuit connected in parallel with the capacitance circuit, and configured to generate the oscillation signal.

The capacitance circuit may include a first and a second capacitance of a capacitor device; and a touch capacitance generated in response to a touch to the first touch member, and connected in parallel with one of the first capacitance and the second capacitance.

The sensing coil may include a coil layer comprising the first inductance wiring, and connected between the first terminal and the second terminal; a first insulating layer stacked on a first surface of the coil layer; and a first conductor layer stacked on the first insulating layer and having the first conductive plate electrically connected to one of the first terminal and the second terminal of the coil layer through a first conductor via hole disposed in the first insulating layer.

The sensing coil may include a coil layer comprising the first inductance wiring connected between the first terminal and the second terminal; a first insulating layer stacked on a first surface of the coil layer; a first conductor layer stacked on the first insulating layer, and comprising the first conductive plate electrically connected to one of the first terminal and the second terminal of the coil layer through a first conductor via hole disposed in the first insulating layer; a second insulating layer stacked on a second surface of the coil layer; and a second conductor layer stacked on the second insulating layer and comprising a second conductive plate electrically connected to another of the first terminal and the second terminal of the coil layer through a second conductor via hole disposed in the second insulating layer.

The sensing coil may include a coil layer include the first inductance wiring connected between the first terminal and the second terminal, a first insulating layer stacked on a first surface of the coil layer; and a first conductor layer stacked on the first insulating layer, and the first conductor layer comprises: a first conductive plate electrically connected to the first terminal of the coil layer through a first conductor via hole disposed in the first insulating layer; and a second conductive plate spaced apart from the first conductive plate and electrically connected to a second terminal of the coil layer through a second conductor via hole disposed in the first insulating layer.

The first touch member may include the first insulated hole disposed to face the first conductive plate of the sensing coil; and a second insulated hole disposed to face the second conductive plate of the sensing coil.

The first conductive plate may be spaced apart from the first touch member.

The device may be any one of a Bluetooth headset, a Bluetooth earpiece, smart glasses; a virtual reality (VR) headset, an Augmented Reality (AR) headset, a laptop, a computer, a smart phone, an entrance key of a vehicle, and a stylus touch pen.

In a general aspect, sensing coil includes a first inductance wiring comprising a first terminal and a second terminal connected to a circuit unit; and a first conductive plate electrically connected to one of the first terminal and the second terminal, insulated from the first inductance wiring, and configured to form a capacitance with a touch object through a first insulated hole of a touch member.

The sensing coil may include a coil layer comprising the first inductance wiring, and connected between the first terminal and the second terminal; a first insulating layer stacked on a first surface of the coil layer; and a first conductor layer stacked on the first insulating layer and comprising the first conductive plate electrically connected to one of the first terminal and the second terminal of the coil layer through a first conductor via hole disposed in the first insulating layer.

The sensing coil may include a coil layer comprising the first inductance wiring connected between the first terminal and the second terminal, a first insulating layer stacked on a first surface of the coil layer; a first conductor layer stacked on the first insulating layer, and comprising the first conductive plate electrically connected to one of the first terminal and the second terminal of the coil layer through a first conductor via hole disposed in the first insulating layer; a second insulating layer stacked on a second surface of the coil layer; and a second conductor layer stacked on the second insulating layer and comprising a second conductive plate electrically connected to another of the first terminal and the second terminal of the coil layer through a second conductor via hole disposed in the second insulating layer.

The sensing coil may include a coil layer comprising the first inductance wiring connected between the first terminal and the second terminal, a first insulating layer stacked on a first surface of the coil layer; and a first conductor layer stacked on the first insulating layer, and the first conductor layer may include a first conductive plate electrically connected to the first terminal of the coil layer through a first conductor via hole disposed in the first insulating layer; and a second conductive plate spaced apart from the first conductive plate and electrically connected to the second terminal of the coil layer through a second conductor via hole disposed in the first insulating layer.

In a general aspect, an electronic device includes a touch interaction unit integrally formed with a housing and comprising a first touch member including a first insulated hole; a sensing coil disposed inside the first touch member, an oscillation circuit connected to the sensing coil, and configured to generate an oscillation signal having a variable resonance frequency based on a touch capacitance generated when the first touch member is touched; and a touch detection circuit configured to detect a touch interaction based on the oscillation signal, wherein the sensing coil includes a first inductance wiring comprising a first terminal and a second terminal, and configured to face the first insulated hole; and a first conductive plate electrically connected to one of the first terminal and the second terminal, spaced apart from the first touch member, and configured to form a capacitance with a touch object through the first insulated hole.

In a general aspect, a touch operation sensing device includes a touch interaction switch, a first touch member, a sensing coil disposed inside the first touch member, an oscillation circuit connected to the sensing coil, and configured to generate an oscillation signal having a variable resonance frequency based on a reactance of a touch to the first touch member; and a touch detection circuit configured to detect a touch operation based on the generated oscillation signal.

The sensing coil may include an inductance wiring comprising a first terminal and a second terminal; and a conductive plate electrically connected to at least one of the first terminal and the second terminal, and configured to form a capacitance with a touch object.

Other features and aspects will be apparent from the following detailed description, the drawings, and the claims.

### BRIEF DESCRIPTION OF DRAWINGS

FIG. 1 illustrates an example of the exterior of a mobile device, in accordance with one or more embodiments.

FIG. 2 is a cross-sectional view of an example electrical apparatus and a touch operation sensing device, in accordance with one or more embodiments.

FIG. 3 illustrates an example of an oscillation circuit during a non-touch period, in accordance with one or more embodiments.

FIG. 4 illustrates an example of an oscillation circuit at the time of a touch, in accordance with one or more embodiments.

FIG. 5 illustrates an example of an oscillation circuit during a non-touch period, in accordance with one or more embodiments.

FIG. 6 illustrates an example of an oscillation circuit at the time of a touch, in accordance with one or more embodiments.

FIG. 7 illustrates an example of a sensing coil, in accordance with one or more embodiments.

FIG. 8 illustrates an example of a sensing coil, in accordance with one or more embodiments.

FIG. 9 illustrates an example of a sensing coil, in accordance with one or more embodiments.

FIG. 10 illustrates an example of a connection of a sensing coil, in accordance with one or more embodiments.

FIG. 11 illustrates an example of a connection of a sensing coil, in accordance with one or more embodiments.

FIG. 12 illustrates an example of a connection of a sensing coil, in accordance with one or more embodiments.

FIG. 13A illustrates an example of a typical physical smartphone key, and

FIG. 13B illustrates an example of a smartphone touch key, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative size, proportions, and depiction of elements in the drawings may be exaggerated for clarity, illustration, and convenience.

Unless otherwise defined, all terms, including technical and scientific terms, used herein have the same meaning as commonly understood by one of ordinary skill in the art to which this disclosure pertains after an understanding of the disclosure of this application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

Subsequently, examples are described in further detail with reference to the accompanying drawings.

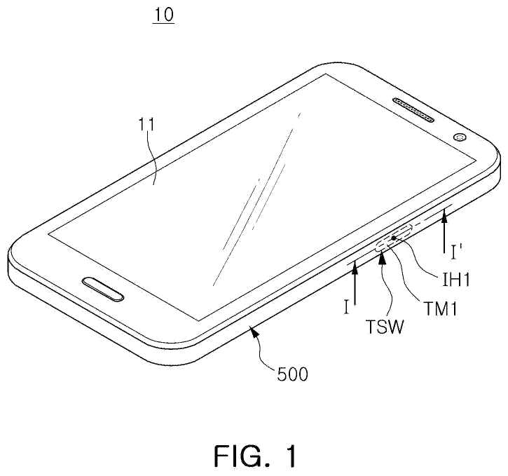

FIG. 1 illustrates an example of the exterior of a mobile device, in accordance with one or more embodiments.

Referring to FIG. 1, a mobile device 10 according to an example may include a touch screen 11, a housing 500, and a touch interaction switch, or input operation switch TSW that includes a first touch or operating member TM1 that replaces a mechanical button switch.

In an example, the first touch member TM1 may be integrally formed with the housing 500. In this example, “integrally formed” may mean that it is formed of a single body at the time of manufacture regardless of whether the same material is used in the manufacturing process, or whether different materials are used in the manufacturing process, the first touch member may not be separated from the housing after the manufacture, and the structure may be a single structure with no gaps at all, and may not be a mechanically separated structure.

In an example, the first touch member TM1 may include a first insulated hole IH1 which is a through-hole in the middle thereof, and an internal insulating state of the first insulated hole IH1 may not be filled with a specific material, and may be in a space or void state, or may be in a state filled with insulating material. For example, the internal insulating state of the first insulated hole IH1 may be filled with an insulating material for waterproofing and moisture proofing.

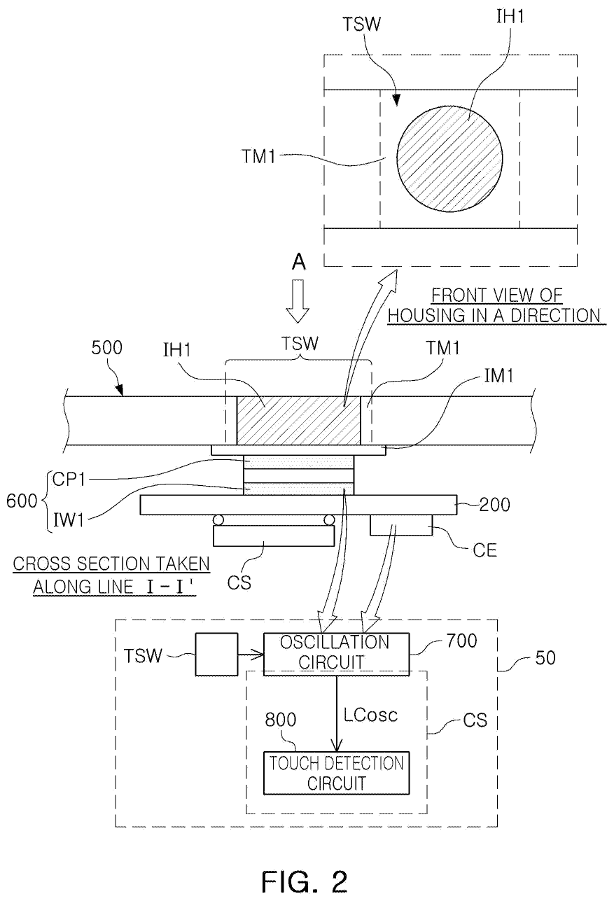

In a non-limiting example, the shape of the first insulated hole IH1 may be circular, as illustrated in FIG. 2, but is not limited thereto, and may be formed in various forms such as an elongated rectangle.

Although FIG. 1 illustrates an example in which the touch interaction switch TSW includes a single touch member TM1, this is for convenience of description, and the touch interaction switch TSW may not be limited to a single touch member as described above. In an example, the number of touch members may be expanded to a number greater than one, and may be implemented in a same manner as the single touch member TM1.

In a non-limiting example, referring to FIG. 1, the mobile device 10 may be a portable device, such as, but not limited to, a Bluetooth earpiece, smart glasses, a laptop, a notebook, a personal computer, a virtual reality (VR) device, an augmented reality (AR) device, and a smartphone, a stylus touch pen, or may be a wearable device, such as, but not limited to, a smartwatch, and is not limited to a specific device, and may be a portable or wearable electrical apparatus or an electrical apparatus having a switch for operation control.

The housing 500 may be an outer case exposed to the outside of the electrical apparatus. For example, when the touch operation sensing device is applied to a mobile device, the housing may be a cover disposed on, for example, a side (a side surface) of the mobile device 10. For example, the housing 500 may be integrally formed with a cover disposed on the rear surface of the mobile device 10, or may be separated from the cover disposed on the rear surface of the mobile device 10.

In this manner, the housing 500 may be an external case of an electrical apparatus, and is not particularly limited to a specific position, form, or structure.

FIG. 2 illustrates an example of an electrical apparatus and a touch operation sensing device having a cross-sectional structure taken along line I-I′ of FIG. 1.

Referring to FIGS. 1 and 2, the electrical apparatus 10 may include the touch interaction switch TSW that is integrally formed with the housing 500, and a touch operation sensing device 50 disposed inside the housing 500.

The touch operation sensing device 50 may include a sensing coil 600 inside the touch interaction switch TSW, an oscillation circuit 700, and a touch detection circuit 800.

The touch interaction switch TSW may be integrally formed with the housing 500 and may include the conductive first touch member TM1 having the first insulated hole IH1.

The oscillation circuit 700 may include the sensing coil 600 disposed inside the first touch member TM1, and a resonance frequency may be varied depending on a touch capacitance generated by the interaction of a touch body (e.g., a human hand), the first insulated hole IH1, and the sensing coil 600, when the first touch member TM1 is touched, and the oscillation circuit 700 may generate an oscillation signal LCosc having this resonance frequency.

The touch detection circuit 800 may detect a touch interaction using the oscillation signal LCosc from the oscillation circuit 700.

The sensing coil 600 may include a first inductance wiring IW1 and a first conductive plate CP1.

In a non-limiting example, the first inductance wiring IW1 may be disposed inside the touch interaction switch TSW and may include a first terminal CT1 and a second terminal CT2 connected to the circuit unit CS or the oscillation circuit 700.

The first conductive plate CP1 may be electrically connected to one of the first terminal CT1 and the second terminal CT2 of the first inductance wiring IW1 and spaced apart from the first touch member TM1. The first conductive plate CP1 may be disposed to face an inner side of the first touch member TM1 to form a capacitance with a touch object (e.g., a hand) through the first insulated hole IH1.

For example, the sensing coil 600 may be disposed to have a predetermined distance from an inner side of the first touch member TM1 to prevent an electrical connection between the first touch member TM1 and the sensing coil 600.

In an example, the touch operation sensing device may further include a first insulating member IM1. In an example, the first insulating member IM1 may be disposed between the inner surface of the first touch member TM1 and the sensing coil 600 to prevent an electrical connection between the first touch member TM1 and the sensing coil 600.

In a non-limiting example, the first insulating member IM1 may be a coating material implemented by a coating process, or a painting material implemented by a painting process, and may be a member having an insulating function. Therefore, the first insulating member IM1 is not limited thereto. A diameter Dia of the first insulated hole IH1 may be greater than a length of the first conductive plate CP1. However, the examples are not limited thereto.

For the drawings of examples, unnecessary description of the same reference numerals and components of the same function may be omitted, and details of differences will be described for the drawings.

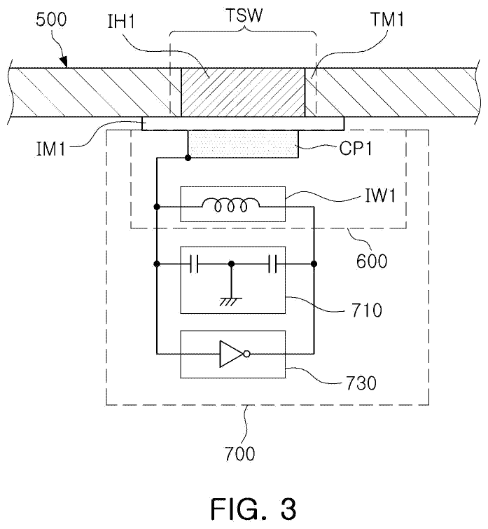

FIG. 3 illustrates an example of an oscillation circuit during a non-touch period, in accordance with one or more embodiments.

Referring to FIG. 3, the first insulated hole IH1 may include a through-portion that penetrates through the first touch member TM1, and an insulating material IM that fills the through-portion.

The first insulating member IM1 may be disposed between the first conductive plate CP1 of the sensing coil 600 and the first touch member TM1.

The first conductive plate CP1 may be disposed to face the first insulated hole IH1.

The oscillation circuit 700 may include a sensing coil 600, a capacitance circuit 710, and an amplifying circuit 730.

The sensing coil 600 may include the first inductance wiring IW1 having a predetermined inductance, and the first conductive plate CP1 to form a relatively larger capacitance with the touch object (e.g., the hand) during touch interaction through the first insulated hole IH1.

The capacitance circuit 710 may include a first capacitance C1 and a second capacitance C2 for resonance.

The amplifying circuit 730 may include an inverter or an amplifier to generate an oscillation signal by maintaining resonance by the sensing coil 600 and the capacitance circuit 710.

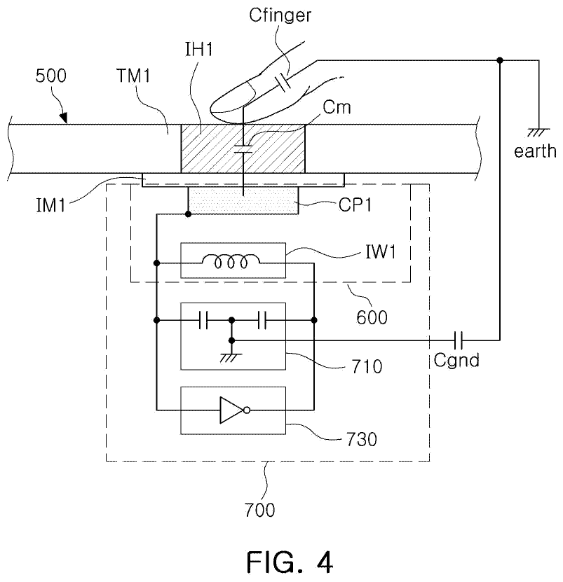

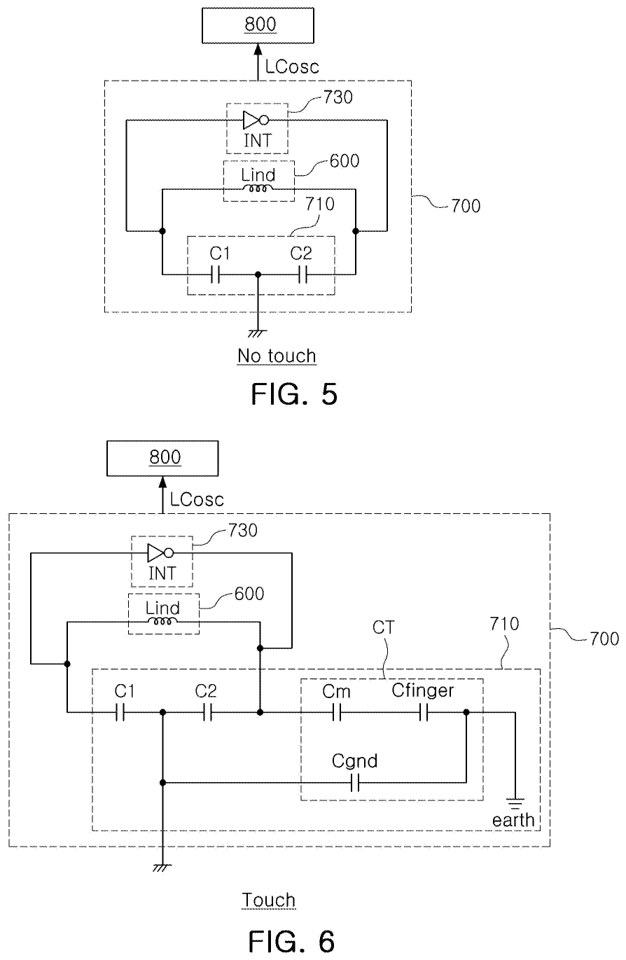

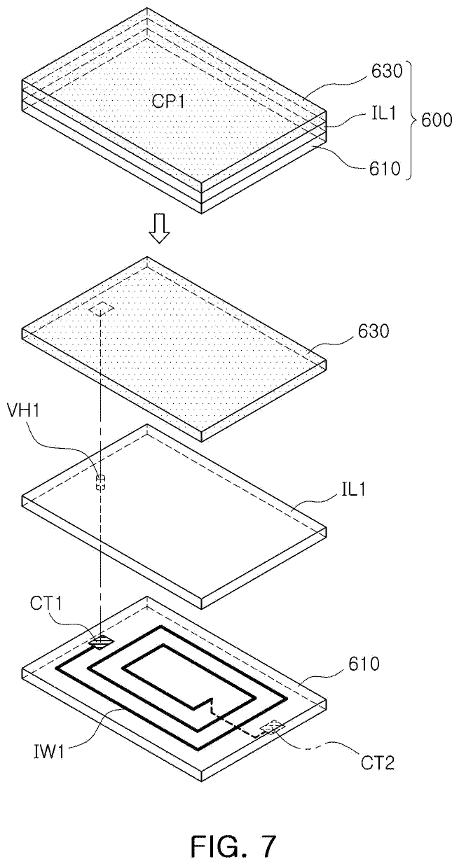

FIG. 4 is an illustration of an example oscillation circuit at the time of a touch, FIG. 5 is an illustration of an oscillation circuit at the time of no touch, and FIG. 6 is illustration of an oscillation circuit at the time of a touch.

Referring to FIGS. 3 and 5, the oscillation circuit 700 may include a sensing coil 600, a capacitance circuit 710, and an amplifying circuit 730.

The sensing coil 600 may include an inductance (Lind).

The capacitance circuit 710 may be connected in parallel with the sensing coil 600 through a first terminal CT1 and a second terminal CT2 of the sensing coil 600, and may include a first capacitance C1 and a second capacitance C2 provided by a first capacitor device CE1. An intermediate node of the first capacitance C1 and the second capacitance C2 may be connected to a ground.

The amplifying circuit 730 may be connected in parallel with the capacitance circuit 710 to generate the oscillation signal LCosc.

Referring to FIGS. 4 and 6, the capacitance circuit 710 may include the first and second capacitances C1 and C2 and a touch capacitance CT.

The first and second capacitances C1 and C2 are capacitances obtained by a capacitor device CE.

The touch capacitance CT is a capacitance generated when the first touch member TM1 is touched, and may be connected in parallel with one of the first and second capacitances C1 and C2. For example, when there is a touch, the touch capacitance CT is connected in parallel with one (C1 or C2) of the first and second capacitances (C1+C2) of the first capacitor device CE1, and may include a plurality of capacitances (Cm, Cfinger, Cgnd) connected in series with each other.

In this example, Cm may be a capacitance generated by the first insulated hole IH1 and the first conductive plate CP1 when touched, Cfinger may be a finger capacitance, and Cgnd may be a ground capacitance between the circuit ground and earth.

FIG. 7 illustrates an example of a sensing coil, in accordance with one or more embodiments.

Referring to FIG. 7, the sensing coil 600 may include a coil layer 610, a first insulating layer IL1, and a first conductor layer 630.

The coil layer 610 may include the inductance wiring IW1 connected between the first terminal CT1 and the second terminal CT2.

The first insulating layer IL1 may be stacked on one surface of the coil layer 610 to insulate the coil layer 610 and the first conductor layer 630 from each other.

The first conductor layer 630 may include the first conductive plate CP1 stacked on the first insulating layer IL1 and electrically connected to one of the first terminal CT1 and the second terminal CT2 of the coil layer 610 through a first conductor via hole VH1 formed in the first insulating layer IL1.

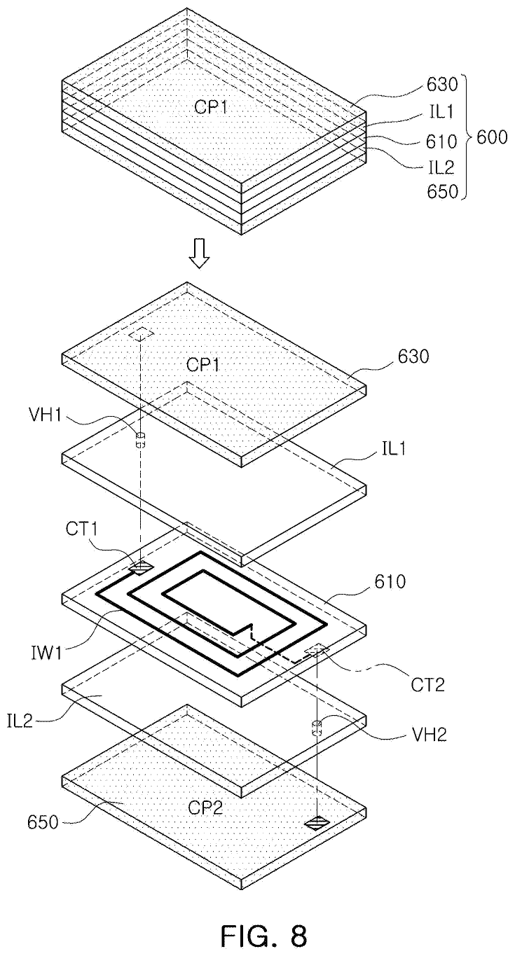

FIG. 8 illustrates an example of a sensing coil, in accordance with one or more embodiments.

Referring to FIG. 8, the sensing coil 600 may include a coil layer 610, a first insulating layer IL1, a first conductor layer 630, a second insulating layer 1L2, and a second conductor layer 650.

The coil layer 610 may include the inductance wiring IW1 connected between the first terminal CT1 and the second terminal CT2.

The first insulating layer IL1 may be stacked on one surface of the coil layer 610 and may insulate the coil layer 610 from the first conductor layer 630.

The first conductor layer 630 may include the first conductive plate CP1 stacked on the first insulating layer IL1 and electrically connected to one of the first terminal CT1 and the second terminal CT2 of the coil layer 610 through the first conductor via hole VH1 formed in the first insulating layer IL1.

The second insulating layer 1L2 may be stacked on the other surface of the coil layer 610 (on the coil layer 610), and may insulate the coil layer 610 and the second conductor layer 650 from each other.

The second conductor layer 650 may include a second conductive plate CP2 stacked on the second insulating layer IL2 and electrically connected to the other of the first terminal CT1 and the second terminal CT2 through a second conductor via hole VH2 formed in the second insulating layer IL2.

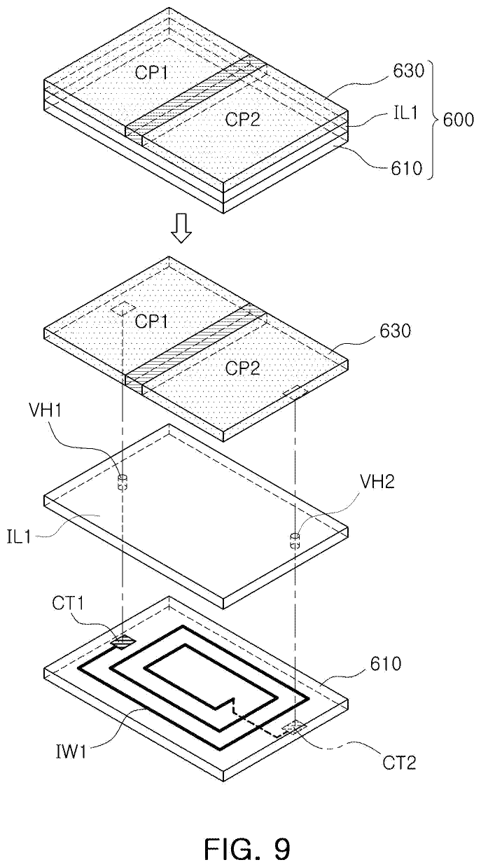

FIG. 9 illustrates an example of a sensing coil, in accordance with one or more embodiments.

Referring to FIG. 9, the sensing coil 600 may include a coil layer 610, a first insulation layer IL1, and a first conductor layer 630.

The coil layer 610 may include the inductance wiring IW1 connected between the first terminal CT1 and the second terminal CT2.

The first insulating layer IL1 may be stacked on one surface of the coil layer 610, and may insulate the coil layer 610 and the first conductor layer 630 from each other.

The first conductor layer 630 may include a first conductive plate CP1 stacked on the first insulating layer IL1 and electrically connected to one of the first terminal CT1 and the second terminal CT2 of the coil layer 610 through the first conductor via hole VH1 formed in the first insulating layer IL1, and a second conductive plate CP2 stacked on the first insulating layer IL1, spaced apart from the first conductive plate CP1 and electrically connected to the other of the first terminal CT1 and the second terminal CT2 of the coil layer 610 through the second conductor via hole VH2 formed in the first insulating layer IL1.

In a non-limiting example, although the space between the first conductive plate CP1 and the second conductive plate CP2 may be empty, the space may also be filled with an insulating material for structural robustness.

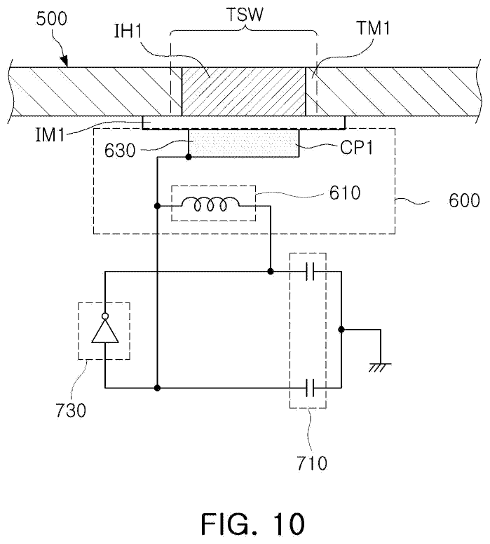

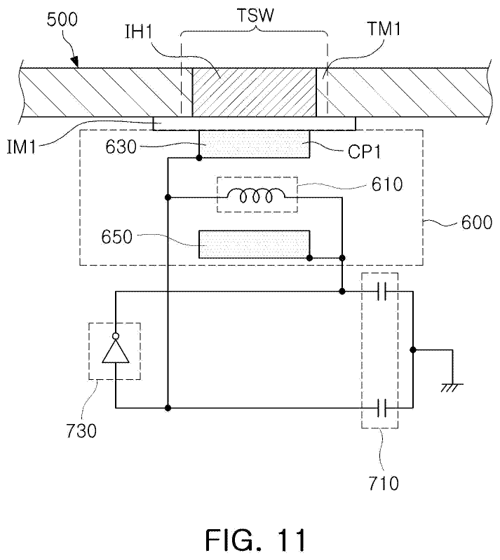

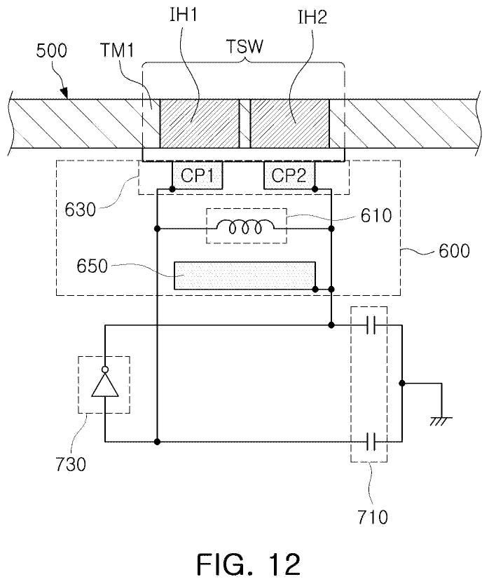

FIG. 10 illustrates an example of a connection of the sensing coil of FIG. 7, FIG. 11 illustrates an example of a connection of the sensing coil of FIG. 8, and FIG. 12 illustrates an example of a connection of the sensing coil of FIG. 9.

Referring to FIGS. 7 and 10, the first touch member TM1 may include the first insulated hole IH1. The first insulated hole IH1 may be disposed to face the first conductive plate CP1 of the sensing coil 600.

The inductance wiring IW1 of the sensing coil 600 may be connected in parallel with the capacitance circuit 710 and the amplifying circuit 730.

Referring to FIGS. 8 and 11, the first touch member TM1 may include the first insulated hole IH1. The first insulated hole IH1 may be disposed to face the first conductive plate CP1 of the sensing coil 600.

The inductance wiring IW1 of the sensing coil 600 may be connected in parallel with the capacitance circuit 710 and the amplifying circuit 730.

Referring to FIGS. 9 and 12, the first touch member TM1 may include a first insulated hole IH1, and a second insulated hole IH2. The first insulated hole IH1 may be disposed to face a first conductive plate CP1 of the sensing coil 600, and the second conductive hole IH2 may be disposed to face a second conductive plate CP2 of the sensing coil 600.

The inductance wiring IW1 of the sensing coil 600 may be connected in parallel with the capacitance circuit 710 and the amplifying circuit 730.

In the examples, a diameter of each of the first insulated hole IH1 and the second insulated hole IH2 may be greater than a length of each of the first conductive plate CP1 and the second conductive plate CP2, but examples thereof are not limited thereto.

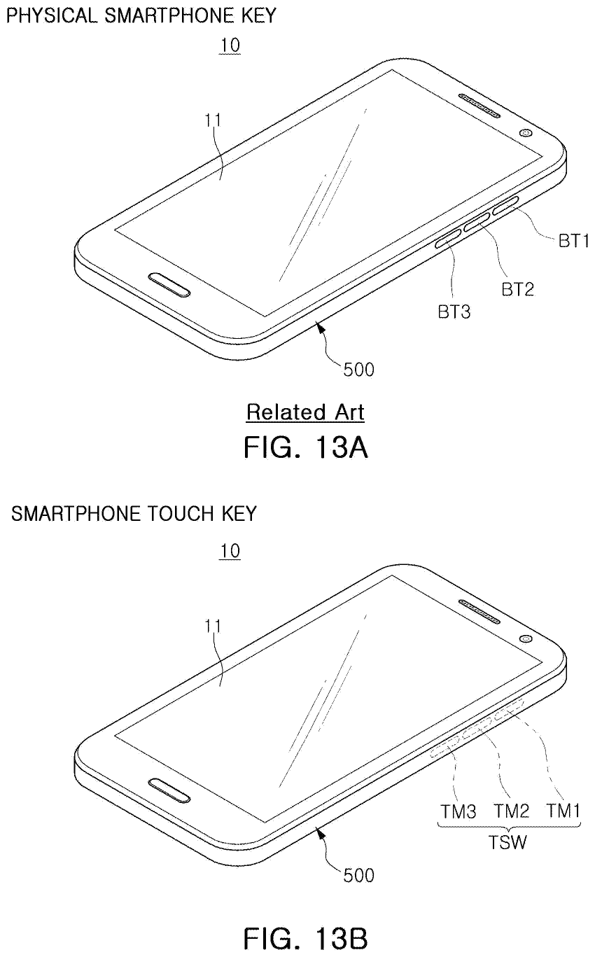

FIG. 13A illustrates a typical physical smartphone key, and FIG. 13B illustrates an example of a smartphone touch key, in accordance with one or more embodiments.

Referring to FIG. 13A, an example of typical protruding physical smartphone keys BT1, BT2 and BT3 installed in a smartphone is illustrated.

Referring to FIG. 13B, an example of touch keys TM1, TM2 and TM3 installed in a smartphone, in accordance with one or more embodiments, is illustrated.

As set forth above, according to an example, when an inductor element such as a coil disposed inside the housing is used as a sensing element, the structure of the inductor element and the touch member integrated with the housing may be improved, thereby improving sensing sensitivity.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A touch operation sensing device comprising a touch interaction switch integrally formed with a housing, the touch interaction switch comprising a first conductive touch member including a first insulated hole, the touch operation sensing device comprising:
a sensing coil disposed inside the first touch member;
an oscillation circuit connected to the sensing coil, and configured to generate an oscillation signal having a variable resonance frequency based on a touch capacitance generated when the first touch member is touched; and
a touch detection circuit configured to detect a touch operation based on the generated oscillation signal,
wherein the sensing coil comprises:
a first inductance wiring comprising a first terminal and a second terminal, and configured to face the first insulated hole; and
a first conductive plate electrically connected to one of the first terminal and the second terminal, and configured to form a capacitance with a touch object through the first insulated hole.

2. The device of claim 1, wherein the sensing coil is disposed to be spaced apart from an inner side of the first touch member.

3. The device of claim 1, further comprising a first insulating member disposed between an inner side of the first touch member and the sensing coil.

4. The device of claim 1, wherein the first insulated hole comprises a through-portion that penetrates through the first touch member and an insulating material that fills the through-portion.

5. The device of claim 4, wherein the first conductive plate is disposed to face the first insulated hole.

6. The device of claim 3, wherein the oscillation circuit comprises:
a capacitance circuit connected in parallel with the first inductance wiring through a first terminal and a second terminal; and
an amplifying circuit connected in parallel with the capacitance circuit, and configured to generate the oscillation signal.

7. The device of claim 6, wherein the capacitance circuit comprises:
a first and a second capacitance of a capacitor device; and
a touch capacitance generated in response to a touch to the first touch member, and connected in parallel with one of the first capacitance and the second capacitance.

8. The device of claim 1, wherein the sensing coil comprises:
a coil layer comprising the first inductance wiring, and connected between the first terminal and the second terminal;
a first insulating layer stacked on a first surface of the coil layer; and
a first conductor layer stacked on the first insulating layer and having the first conductive plate electrically connected to one of the first terminal and the second terminal of the coil layer through a first conductor via hole disposed in the first insulating layer.

9. The device of claim 1, wherein the sensing coil comprises:
a coil layer comprising the first inductance wiring connected between the first terminal and the second terminal;
a first insulating layer stacked on a first surface of the coil layer;
a first conductor layer stacked on the first insulating layer, and comprising the first conductive plate electrically connected to one of the first terminal and the second terminal of the coil layer through a first conductor via hole disposed in the first insulating layer;
a second insulating layer stacked on a second surface of the coil layer; and
a second conductor layer stacked on the second insulating layer and comprising a second conductive plate electrically connected to another of the first terminal and the second terminal of the coil layer through a second conductor via hole disposed in the second insulating layer.

10. The device of claim 2, wherein the sensing coil comprises:
a coil layer comprising the first inductance wiring connected between the first terminal and the second terminal;
a first insulating layer stacked on a first surface of the coil layer; and
a first conductor layer stacked on the first insulating layer, and the first conductor layer comprises:
a first conductive plate electrically connected to the first terminal of the coil layer through a first conductor via hole disposed in the first insulating layer; and
a second conductive plate spaced apart from the first conductive plate and electrically connected to a second terminal of the coil layer through a second conductor via hole disposed in the first insulating layer.

11. The device of claim 10, wherein the first touch member comprises:
the first insulated hole disposed to face the first conductive plate of the sensing coil; and
a second insulated hole disposed to face the second conductive plate of the sensing coil.

12. The device of claim 1, wherein the first conductive plate is spaced apart from the first touch member.

13. The device of claim 1, wherein the device is any one of a Bluetooth headset, a Bluetooth earpiece, smart glasses; a virtual reality (VR) headset, an Augmented Reality (AR) headset, a laptop, a computer, a smart phone, an entrance key of a vehicle, and a stylus touch pen.

14. A sensing coil comprising:
a first inductance wiring comprising a first terminal and a second terminal connected to a circuit unit; and
a first conductive plate electrically connected to one of the first terminal and the second terminal, insulated from the first inductance wiring, and configured to form a capacitance with a touch object through a first insulated hole of a touch member.

15. The sensing coil of claim 14, wherein the sensing coil comprises:
a coil layer comprising the first inductance wiring, and connected between the first terminal and the second terminal;
a first insulating layer stacked on a first surface of the coil layer; and
a first conductor layer stacked on the first insulating layer and comprising the first conductive plate electrically connected to one of the first terminal and the second terminal of the coil layer through a first conductor via hole disposed in the first insulating layer.

16. The sensing coil of claim 14, wherein the sensing coil comprises:
a coil layer comprising the first inductance wiring connected between the first terminal and the second terminal;
a first insulating layer stacked on a first surface of the coil layer;
a first conductor layer stacked on the first insulating layer, and comprising the first conductive plate electrically connected to one of the first terminal and the second terminal of the coil layer through a first conductor via hole disposed in the first insulating layer;
a second insulating layer stacked on a second surface of the coil layer; and
a second conductor layer stacked on the second insulating layer and comprising a second conductive plate electrically connected to another of the first terminal and the second terminal of the coil layer through a second conductor via hole disposed in the second insulating layer.

17. The sensing coil of claim 14, wherein the sensing coil comprises:
a coil layer comprising the first inductance wiring connected between the first terminal and the second terminal;
a first insulating layer stacked on a first surface of the coil layer; and
a first conductor layer stacked on the first insulating layer, and
the first conductor layer comprises:
a first conductive plate electrically connected to the first terminal of the coil layer through a first conductor via hole disposed in the first insulating layer; and
a second conductive plate spaced apart from the first conductive plate and electrically connected to the second terminal of the coil layer through a second conductor via hole disposed in the first insulating layer.

18. An electronic device comprising:
a touch interaction unit integrally formed with a housing and comprising a first touch member including a first insulated hole;
a sensing coil disposed inside the first touch member;
an oscillation circuit connected to the sensing coil, and configured to generate an oscillation signal having a variable resonance frequency based on a touch capacitance generated when the first touch member is touched; and
a touch detection circuit configured to detect a touch interaction based on the oscillation signal,
wherein the sensing coil comprises:
a first inductance wiring comprising a first terminal and a second terminal, and configured to face the first insulated hole; and
a first conductive plate electrically connected to one of the first terminal and the second terminal, spaced apart from the first touch member, and configured to form a capacitance with a touch object through the first insulated hole.

19. An electronic device comprising:
a touch interaction switch;
at least one touch member included in the touch interaction switch;
a sensing coil disposed inside the at least one touch member;
an oscillation circuit connected to the sensing coil, and configured to generate an oscillation signal having a variable resonance frequency based on a reactance of a touch to the first touch member; and
a touch detection circuit configured to detect a touch operation based on the generated oscillation signal,
wherein the sensing coil comprises:
an inductance wiring comprising a first terminal and a second terminal; and
a conductive plate electrically connected to at least one of the first terminal and the second terminal, and configured to form a capacitance with a touch object.
